(19) United States
(12) Patent Application Publication
(10) Pub. No.: US 2013/0065399 A1
(43) Pub. Date: Mar. 14, 2013

(54) PLASMA PROCESSING METHOD

(71) Applicant: Tokyo Electron Limited, Tokyo (JP)

(72) Inventors: Hirokazu UDEA, Amagasaki-shi (JP); Tetsuya NISHIZUKA, Amagasaki-shi (JP); Toshihisa NOZAWA, Amagasaki-shi (JP); Takaaki MATSUOKA, Tokyo (JP)

(73) Assignee: TOKYO ELECTRON LIMITED, Tokyo (JP)

(21) Appl. No.: 13/668,367

(22) Filed: Nov. 5, 2012

Related U.S. Application Data
(62) Division of application No. 12/743,047, filed on Jun. 3, 2010.

(30) Foreign Application Priority Data
Nov. 14, 2007 (JP) 2007-295278

(51) Int. Cl. H01L 21/3065; H01L 21/302

(52) U.S. Cl. 438/726; 438/758; 438/710; 257/E21.214; 257/E21.218

(57) ABSTRACT

A plasma processing method includes holding a wafer on a holding stage, generating plasma inside the processing chamber by a plasma generator to define a first processing region having an electron temperature higher than a predetermined value and a second processing region having an electron temperature lower than the predetermined value, moving the holding stage for the wafer to be positioned in the first processing region, performing the plasma processing of the wafer positioned in the first processing region, moving the holding stage for the wafer to be positioned in the second processing region, and stopping to generate plasma when the wafer is positioned in the second processing region after completion of the plasma processing.

### CROSS-REFERENCE TO RELATED PATENT APPLICATIONS

This application is a divisional application of prior U.S. patent application Ser. No. 12/743,047, filed on Jun. 3, 2010, the entire content of which is incorporated herein by reference, and this application claims the benefit of Japanese Patent Application No. 2007-295278 filed on Nov. 14, 2007 in the Japan Patent Office, the disclosure of which is incorporated herein in its entirety by reference.

### BACKGROUND OF THE INVENTION

1. Field of the Invention

The present invention relates to a plasma processing method for plasma-processing a semiconductor substrate.

2. Description of the Related Art

Semiconductor devices, such as LSI (Large Scale Integrated circuit), are manufactured via a plurality of processes, such as etching, CVD (Chemical Vapor Deposition), and sputtering, performed with respect to a semiconductor substrate (wafer). These processes, such as etching, CVD, and sputtering, may use plasma as an energy supply source, that is, may be plasma etching, plasma CVD, and plasma sputtering.

When manufacturing a semiconductor device, the plasma processes described above are effectively used along with the recent miniaturization or multilayered-wiring of LSI. For example, when performing a plasma process for manufacturing a semiconductor device, such as a MOS (Metal Oxide Semiconductor) transistor, plasma generated by various devices, such as parallel-plate type plasma, ICP (Inductively-coupled Plasma), or ECR (Electron Cyclotron Resonance) plasma, may be used.

Here, when the plasma process is performed on a semiconductor substrate by using the each plasma, electric charges are accumulated in a gate oxide film (gate insulation film) or an adjacent layer included in a MOS transistor, and thus the MOS transistor has plasma damage, such as charge-up.

Here, with respect to a parallel-plate type plasma processing apparatus, a technology of reducing charge-up damage due to plasma is disclosed in Japanese Laid-Open Patent Publication No, 2001-156051. According to Japanese Laid-Open Patent Publication No. 2001-156051, in a plasma processing method conducted in a plasma processing apparatus having a processing chamber, an electrode provided in the processing chamber and supporting a substrate to be processed, and a plasma generator provided in the processing chamber, electric power is supplied to the electrode for supporting the substrate to be processed with a frequency that does not start plasma, before the plasma starts by the plasma generator. Accordingly, before performing a plasma process, an ion-sheath is formed on a surface of the electrode, and charge-up damage to the substrate to be processed while starting plasma is reduced by the ion-sheath.

When a semiconductor substrate is plasma-processed, for example, when a high film-forming rate is required, a plasma process may be performed in a region where an electron temperature of plasma is high, from the viewpoint of process efficiency improvement. However, according to a conventional plasma processing method, for example, if a plasma process is performed when an electron temperature of plasma is high by simply drawing the semiconductor substrate near a plasma-generating source, charge-up damage to a semiconductor substrate may be increased.

### BRIEF SUMMARY OF THE INVENTION

The present invention provides a plasma processing apparatus for increasing efficiency of a plasma process and reducing charge-up damage by plasma.

The present invention also provides a method for plasma-processing a semiconductor substrate, which increases efficiency of a plasma process and reduces charge-up damage by plasma.

According to an aspect of the present invention, there is provided a plasma processing apparatus for plasma-processing a semiconductor substrate disposed in a chamber, the plasma processing apparatus including a plasma generating means for generating plasma by using microwaves as a plasma source in such a way that a first region having a relatively high electron temperature of plasma, and a second region having a lower electron temperature of plasma than the first region are formed in the chamber; a first arranging means for arranging the semiconductor substrate in the first region: a second arranging means for arranging the semiconductor substrate in the second region; and a plasma generation stopping means for stopping the generation of plasma by the plasma generating means, while the semiconductor substrate is arranged in the second region.

According to the plasma processing apparatus, during a plasma process, the plasma processing efficiency may be increased by arranging the semiconductor substrate in the first region having a high electron temperature of plasma. Also, while stopping the generation of plasma, plasma damage caused while stopping the generation of plasma is reduced by arranging the semiconductor substrate in the second region having a low electron temperature of plasma, thereby reducing charge-up damage by plasma.

According to an embodiment, the plasma processing apparatus may further include a semiconductor substrate moving means for arranging the semiconductor substrate in the first region or the second region. The semiconductor substrate moving means may include the first and second arranging means. Accordingly, the semiconductor substrate may be easily arranged in the first region or the second region by using the semiconductor substrate moving means.

According to an embodiment, the plasma processing apparatus may further include a pressure controlling means for controlling a pressure in the chamber. The pressure controlling means may include: the first arranging means for arranging the semiconductor substrate in the first region by relatively reducing the pressure in the chamber; and the second arranging means for arranging the semiconductor substrate in the second region by relatively increasing the pressure in the chamber. Accordingly, the semiconductor substrate may be arranged in the first or second region by controlling the pressure in the chamber by using the pressure controlling means.

According to an embodiment, the electron temperature of plasma in the first region may be higher than 1.5 eV, and the electron temperature of plasma in the second region may be lower than or equal to 1.5 eV.

According to another aspect of the present invention, there is provided a method for plasma-processing a semiconductor substrate disposed in a chamber, the method including: generating plasma by using microwaves as a plasma source in such a way that a first region having a relatively high electron temperature of plasma, and a second region having a lower electron temperature of plasma than the first region are formed in a chamber; plasma-processing the semiconductor substrate by arranging the semiconductor substrate in the first region; arranging the plasma-processed semiconductor substrate in the second region; and stopping the generation of the plasma while the plasma-processed semiconductor substrate is arranged in the second region.

According to the method for plasma-processing a semiconductor substrate, during a plasma process, the plasma processing efficiency may be increased since the semiconductor substrate is plasma-processed while being arranged in the first region having a high electron temperature of plasma. Also, while stopping the generation of plasma, plasma damage caused while stopping the generation of the plasma is reduced by arranging the semiconductor substrate in the second region having a low electron temperature of plasma, thereby reducing charge-up damage by plasma.

### BRIEF DESCRIPTION OF DRAWINGS

FIG. 1 is a cross-sectional view schematically showing a plasma processing apparatus according to an embodiment of the present invention;

FIG. 2 is a diagram showing the plasma processing apparatus of FIG. 1, wherein a holding stage is moved upward;

FIG. 3 is a flowchart showing representative processes in a method for plasma-processing a semiconductor substrate, according to an embodiment of the present invention;

FIG. 4 is a graph showing a relationship between an electron temperature of plasma and a TEG yield;

FIG. 5 is a diagram showing plasma damage of a TEG evaluated when the generation of plasma is stopped in a region where an electron temperature of plasma is 1.5 eV:

FIG. 6 is a diagram showing plasma damage of a TEG evaluated when the generation of plasma is stopped in a region where an electron temperature of plasma is 3 eV;

FIG. 7 is a diagram showing plasma damage of a TEG evaluated when the generation of plasma is stopped in a region where an electron temperature of plasma is 7 eV;

FIG. 8 is a graph showing a relationship between an electron temperature of plasma and a location on a holding stage, for each pressure in a chamber;

FIG. 9 is a graph showing a relationship between an electron density of plasma and a location on a holding stage, for each pressure in a chamber; and

FIG. 10 is a diagram showing a distance X from the center P of a holding stage.

### DETAILED DESCRIPTION OF THE INVENTION

Hereinafter, embodiments of the present invention will be described in detail with reference to the attached drawings.

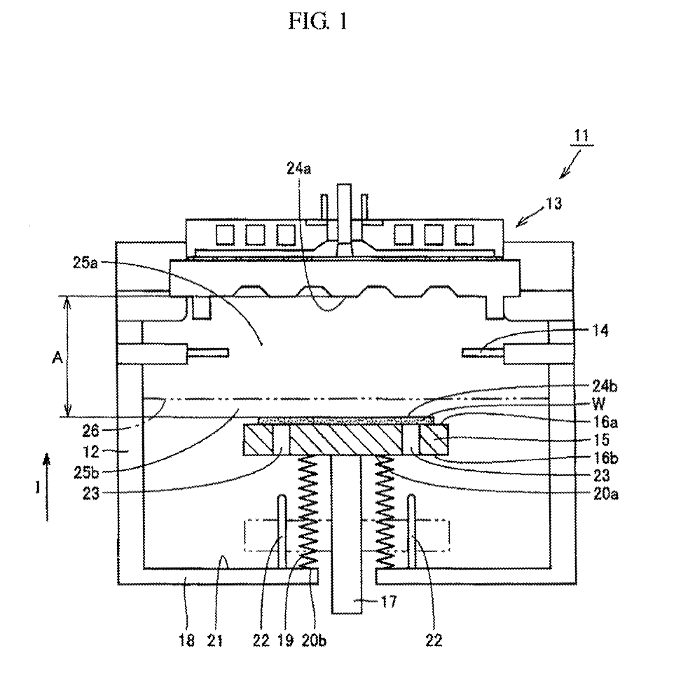

FIG. 1 is a cross-sectional view schematically showing a part of a plasma processing apparatus according to an embodiment of the present invention. Also, in the following drawings, the top of a paper on which a drawing is drawn is assumed to be an upper direction. Furthermore, a semiconductor substrate W to be processed may include a MOS transistor.

Referring to FIG. 1, a plasma processing apparatus 11 includes a sealable chamber (container) 12 for performing a plasma process on the semiconductor substrate W to be processed, by accommodating the semiconductor substrate W, an antenna unit 13 serving as a plasma generating means for generating plasma in the chamber 12 by using microwaves fed from a waveguide, and a gas inlet 14 serving as an inlet path of an etching gas into the chamber 12.

A holding stage 15 having a circular plate shape is disposed in the chamber 12, wherein the semiconductor substrate W is held on an upper surface 16a of the holding stage 15. The holding stage 15 is supported by a support 17 that extends downward from the center of a lower surface 16b of the holding stage 15. A lower part of the support 17 penetrates through a bottom part 18 of the chamber 12. The support 17 may move in an up-and-down direction, i.e., in a direction of or an opposite direction to an arrow I of FIG. 1, by using an elevation mechanism (not shown). By moving the support 17 in an up-and-down direction, the holding stage 15 may also move in an up-and-down direction.

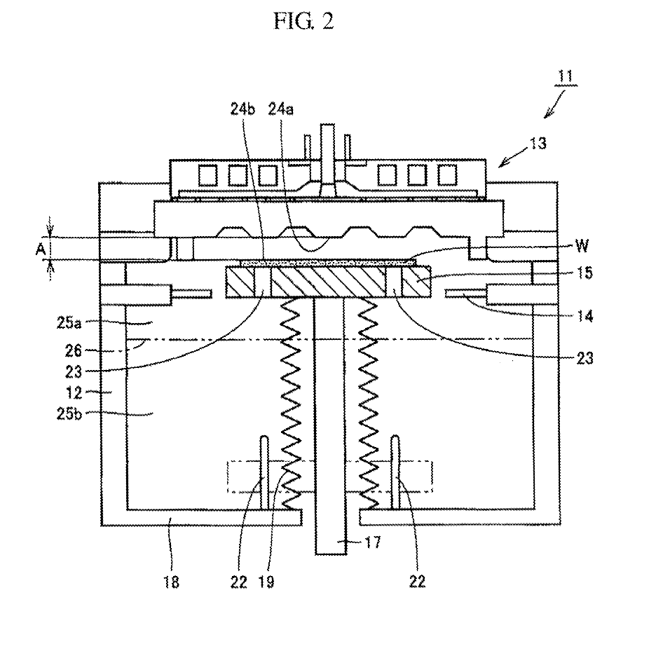

A metal bellows 19 having a pleated box shape that is stretchable in an up-and-down direction is provided in the plasma processing apparatus 11, and surrounds the support 17. An upper part 20a of the metal bellows 19 is closely adhered to the lower surface 16b of the holding stage 15. Also, a lower part 20b of the metal bellows 19 is closely adhered to an upper surface 21 of the bottom part 18 of the chamber 12. The metal bellows 19 may move the holding stage 15 in an up-and-down direction while still maintaining air-tightness in the chamber 12. FIG. 2 is a diagram showing the plasma processing apparatus 11 of FIG. 1, wherein the holding stage 15 is moved upward.

A plurality of pins 22 are included extending upward from the bottom part 18. A through hole 23 is formed in the holding stage 15 so as to correspond to a location of each pin 22. When the holding stage 15 is moved downward, an upper end of the pin 22 that is inserted through the through hole 23 may receive the semiconductor substrate W. The received semiconductor substrate W is transferred by a transfer unit (not shown) that has entered from outside the chamber 12.

The antenna unit 13 includes a slot plate having a circular plate shape having a plurality of slot holes formed in a T-shape when viewed from below. The microwaves fed from the waveguide are emitted into the chamber 12 through the plurality of slot holes. Accordingly, plasma having a uniform electron density distribution may be generated.

Plasma is generated at a lower part of the antenna unit 13 by using the microwaves as a plasma source. Here, an electron temperature of the generated plasma is the highest at a bottom surface 24a of the antenna unit 13, and decreases further away from the bottom surface 24a of the antenna unit 13. In other words, the antenna unit 13 may form a first region 25a having a relatively high electron temperature of plasma and a second region 25b having a lower electron temperature of plasma than the first region 25a, in the chamber 12. In FIGS. 1 and 2, a boundary 26 between the first and second regions 25a and 25b is indicated by a double-dot-dashed line. Here, the boundary 26 indicates a boundary of an electron temperature of plasma in the chamber 12, and is not limited to a line straight in a right and left direction as illustrated in FIGS. 1 and 2.

According to an example of a structure of the plasma processing apparatus 11, for example, the maximum distance between a top surface 24b of the semiconductor substrate W held on the holding stage 15 and the bottom surface 24a of the antenna unit 13 is about 120 mm, and a distance between the holding stage 15 and the gas inlet 14 is about 40 mm. Also, as discharge conditions, a frequency is 2.45 GHz and a pressure is in the range of 0.5 mTorr-5 Torr.

In the plasma processing apparatus 11 having such a structure, if A (mm) denotes a distance from the bottom surface 24a of the antenna unit 13, an electron temperature of plasma is 7 eV at a location where A=15. An electron temperature of plasma is 3 eV at a location where A=25. An electron temperature of plasma is 1.5 eV at a location where A=55. Here, when a region where an electron temperature of plasma is higher than 1.5 eV is the first region 25a, the first region 25a in the chamber 12 is at a location where A<55. When a region where an electron temperature of plasma is lower than or equal to 1.5 eV is the second region 25b, the second region 25b in the chamber 12 is at a location where A≧55. FIG. 1 shows the plasma processing apparatus 11 in which A=55, and FIG. 2 shows the plasma processing apparatus 11 in which A=15.

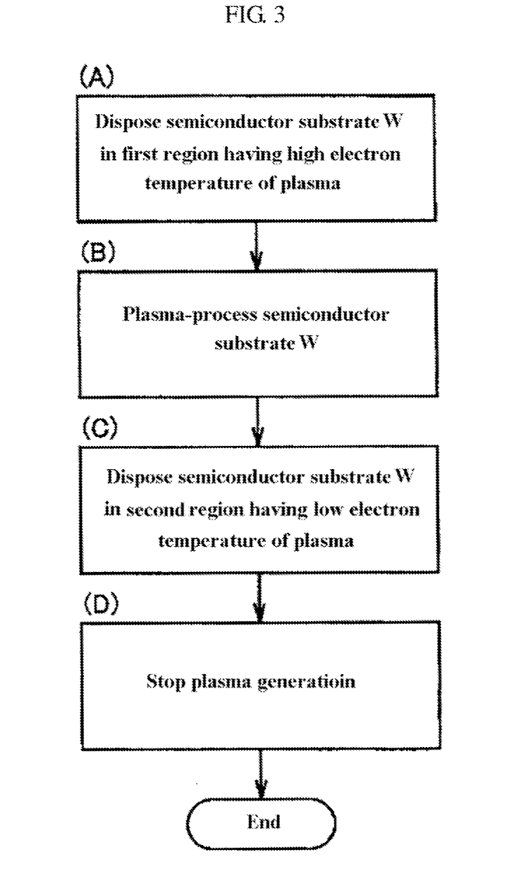

A method for plasma-processing a semiconductor substrate, according to an embodiment of the present invention, will now be described by referring to the plasma processing apparatus 11 of FIGS. 1 and 2. FIG. 3 is a flowchart showing representative processes in the method for plasma-processing a semiconductor substrate, according to the present embodiment.

Referring to FIGS. 1-3, first, the semiconductor substrate W to be processed is held on the holding stage 15 in the chamber 12. Then, the holding stage 15 is moved upward by using the support 17, the metal bellows 19, or the like serving as a first arranging means, like a state shown in FIG. 2. Next, the inside of the chamber 12 is depressurized to a pressure that satisfies the discharge conditions of the microwave plasma. Then, microwaves are generated by a high frequency power supply source, and fed to the antenna unit 13 through the waveguide. As such, the plasma is generated from the antenna unit 13. The plasma is generated in such a way that the first region 25a having an electron temperature of plasma higher than 1.5 eV and the second region 25b having an electron temperature of plasma lower than or equal to 1.5 eV are formed in the chamber 12. At this point, the semiconductor substrate W is disposed in the first region 25a (FIG. 3(A)).

Next, a material gas supplied from the gas inlet 14 reacts with the plasma, and thus a plasma process, such as CVD, is performed on the semiconductor substrate W (FIG. 3(B)). After plasma-processing of the semiconductor substrate W is completed, the holding stage 15 is moved downward by using the support 17, metal bellows 19, or the like serving as a second arranging means so as to arrange the plasma-processed semiconductor substrate W in the second region 25b having a low electron temperature of plasma (FIG. 3(C)). Then, the feeding of plasma to the antenna unit 13 is stopped so as to stop the generation of plasma (FIG. 3(D)). In other words, the generation of plasma is stopped while the plasma-processed semiconductor substrate W is disposed in the second region 25b having the low electron temperature of plasma.

Accordingly, during a plasma process, the plasma process efficiency may be increased since the semiconductor substrate W can be plasma-processed in the first region 25a having an electron temperature of plasma higher than 1.5 eV. Also, while stopping the generation of plasma, plasma damage caused while stopping the generation of plasma is reduced by arranging the semiconductor substrate W in the second region 25b having an electron temperature of plasma lower than or equal to 1.5 eV, thereby reducing charge-up damage caused by plasma.

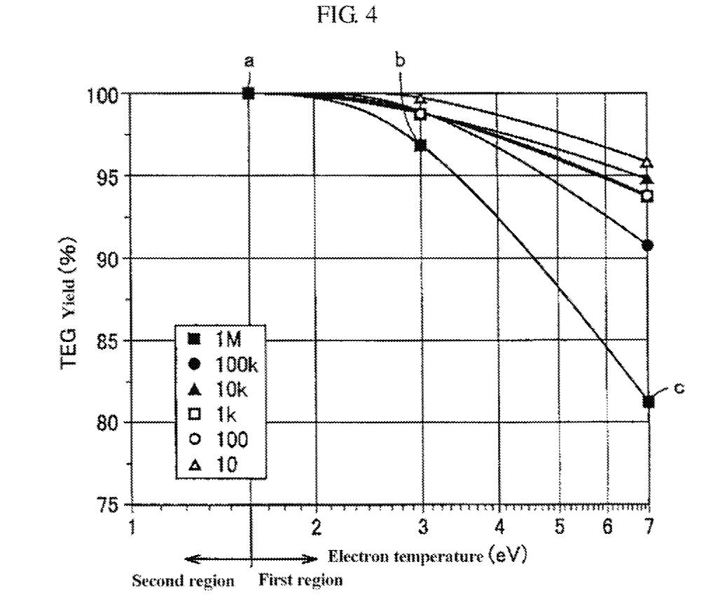

FIG. 4 is a graph showing a relationship between an electron temperature of plasma and a TEG (Test Element Group) yield for evaluating charge-up damage caused by plasma. Referring to FIG. 4, the vertical axis indicates the TEG yield (%), i.e., a proportion of TEGs not subjected to plasma damage, and the horizontal axis indicates an electron temperature (eV) when the generation of plasma is stopped. Here, N₂ plasma is used under a pressure of 20 mTorr, an output power is 3 kW, a bias power is 0 W, N₂ gas flows at a rate of 1000 sccm, and Ar gas flows at a rate of 100 sccm. Each antenna ratio is shown in FIG. 4. Here, the antenna ratio denotes a ratio of a total area of a wiring portion of a to-be-measured transistor that is exposed to plasma and into which charged particle flows to an area of a gate electrode connected to the wiring. As the antenna ratio increases, a probability of exposure to plasma increases. Also, when A=15, electron density is 3.7×10¹¹ cm⁻³, when A=25. electron density is 3.9×10¹¹ cm⁻³, and when A=55, electron density is 3.4×10¹¹ cm⁻³, which are all high electron densities, and are almost similar as the electron density of the plasma.

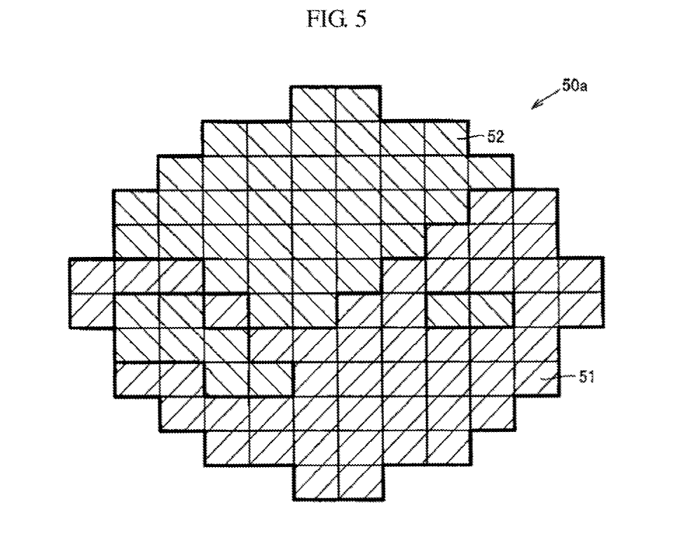

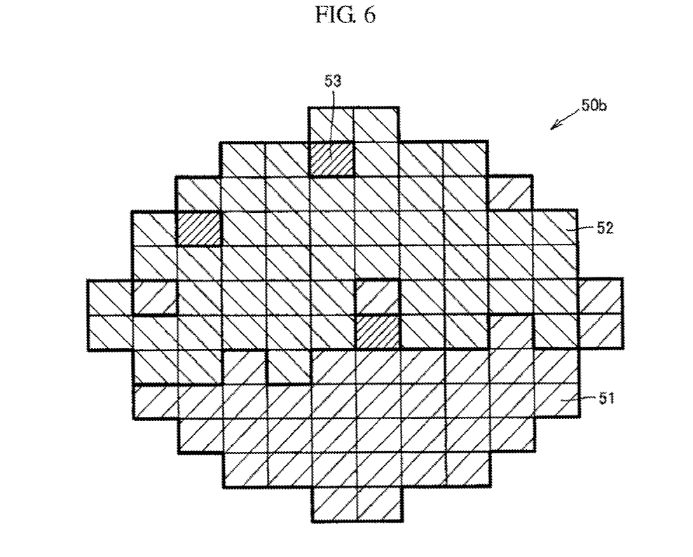

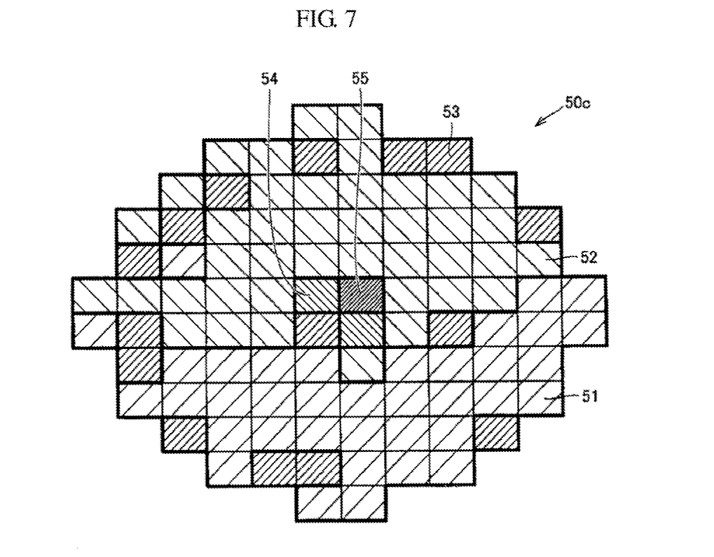

FIG. 5 is a diagram showing plasma damage of a TEG 50a of antenna ratio 1M evaluated at “a” of FIG. 4, i.e., when the generation of plasma is stopped in a region where an electron temperature of plasma is 1.5 eV. FIG. 6 is a diagram showing plasma damage of a TEG 50b of antenna ratio 1M evaluated at “b” of FIG. 4, i.e., when the generation of plasma is stopped in a region where an electron temperature of plasma is 3 eV. FIG. 7 is a diagram showing plasma damage of a TEG 50c of an antenna ratio 1M evaluated at “c” of FIG. 4, i.e., when the generation of plasma is stopped in a region where an electron temperature of plasma is 7 eV. In FIGS. 5-7, regions 51 and 52 denote portions with small plasma damage, and regions 53, 54, and 55 denote portions with large plasma damage. Also, plasma damage increases in an order of the region 53, the region 54, and the region 55.

Referring to FIGS. 4-7, when the generation of plasma is stopped in the region where the electron temperature of plasma is 7 eV, the plasma damage is large since a portion not subjected to the plasma damage is less than 85%. Also, when the plasma is stopped in the region where the electron temperature of plasma is 3 eV, a portion not subjected to the plasma damage is less than 95%. Meanwhile, when the generation of plasma is stopped in the region where the electron temperature of plasma is 1.5 eV, a portion not subjected to the plasma damage is almost 100%.

As described above, according to the plasma processing apparatus 11 and the method for plasma-processing a semiconductor substrate, the plasma processing efficiency may be increased and the charge-up damage by plasma may be reduced.

Also, in the above embodiment, the semiconductor substrate W is arranged in the first or second region by moving up and down the holding stage 15 on which the semiconductor substrate W is held, but the present invention is not limited thereto, and the semiconductor substrate W may be arranged in the first or second region 25a or 25b by fixing the semiconductor substrate W in a predetermined location and controlling a pressure in the chamber.

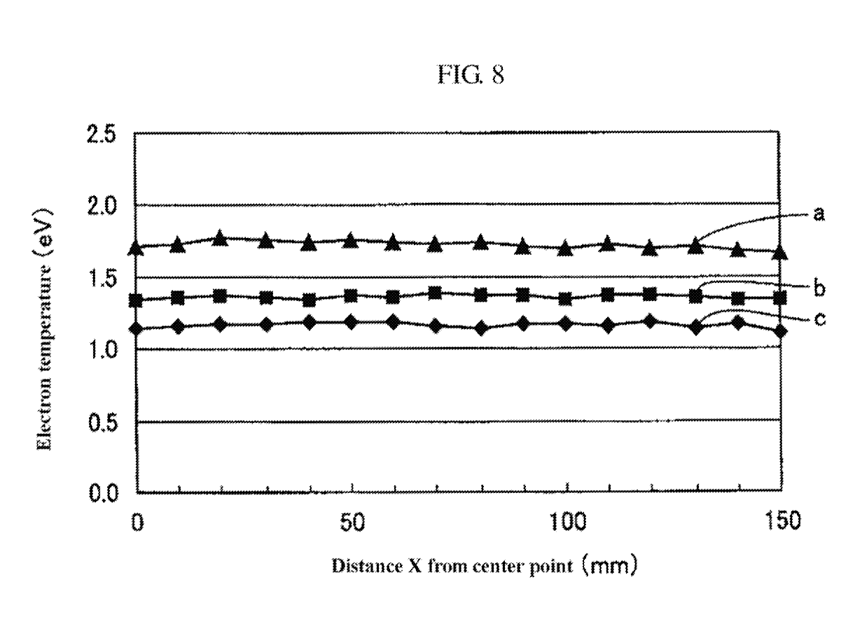

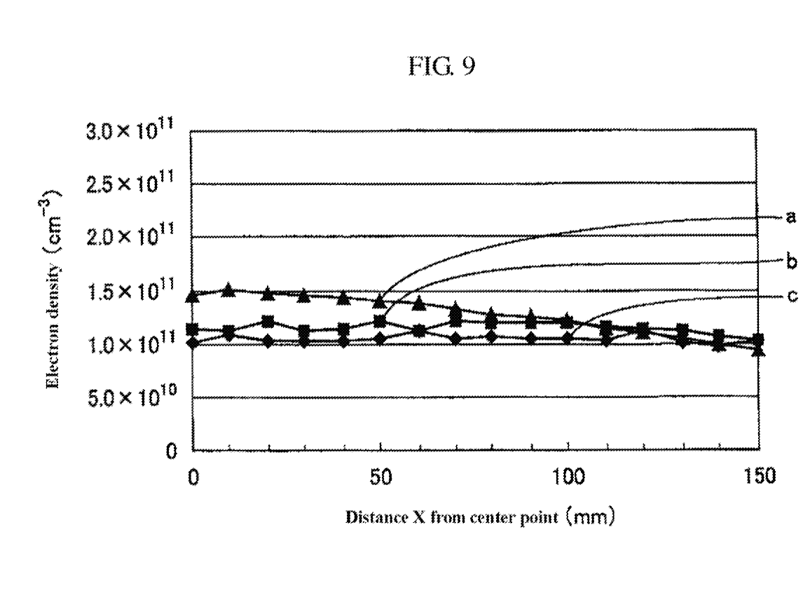

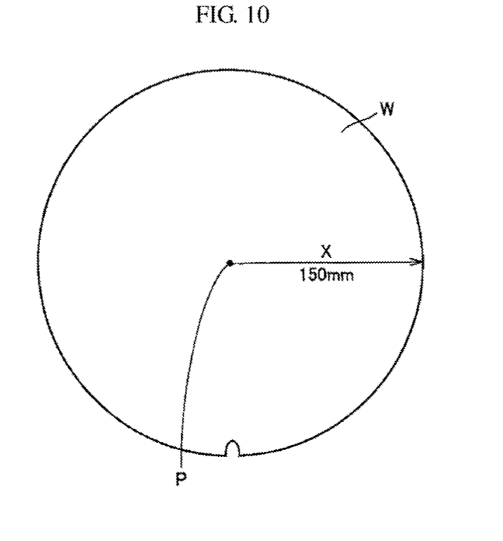

FIG. 8 is a graph showing a relationship between an electron temperature of plasma and a location on the holding stage 15, for each pressure in the chamber 12. FIG. 9 is a graph showing a relationship between an electron density of plasma and a location on the holding stage 15, for each pressure in the chamber 12. FIG. 10 is a diagram showing a distance X from the center P of the holding stage 15. In FIGS. 8 and 9, the horizontal axis denotes the distance X from the center P of the holding stage 15. The vertical axis of FIG. 8 denotes an electron temperature (eV) of plasma on the holding stage 15, and the vertical axis of FIG. 9 denotes electron density (cm⁻³) of plasma in FIGS. 8 and 9, “a” denotes a state when a pressure in the chamber 12 is 10 mTorr, “b” denotes a state when a pressure in the chamber 12 is 20 mTorr, and “c” denotes a state when a pressure in the chamber 12 is 30 mTorr. Also, N₂ gas flows at a rate of 200 sccm and power of a power supply source for generating microwaves is 2000 W.

Referring to FIGS. 8-10, the electron temperatures and electron densities in all of “a”-“c” are almost the same in a surface where the semiconductor substrate W is processed. Here, the electron temperature of plasma on the holding stage 15 may be about 1.7 eV by setting the pressure in the chamber 12 to be lower than 10 mTorr, so as to form the first region 25a. Alternatively, the electron temperature of plasma on the holding stage 15 may be about 1.3 eV by setting the pressure in the chamber 12 to be higher than 20 mTorr, so as to form the second region 25b. In other words, as described above, the semiconductor substrate W on the holding stage 15 may be arranged in the first or second region 25a or 25b by controlling the pressure in the chamber 12, without having to move the holding stage 15 in an up-and-down direction.

In detail, the semiconductor substrate W is arranged in the first region 25a by setting the pressure in the chamber 12 to be lower than or equal to 10 mTorr and the electron temperature of plasma to 1.7 eV, and then the semiconductor substrate W is plasma-processed. After performing the plasma process, the semiconductor substrate W is arranged in the second region 25b by setting the pressure in the chamber 12 to be equal to or greater than 20 mTorr and the electron temperature of plasma to 1.3 eV, and then the generation of plasma is stopped.

In other words, if this will be described in detail with reference to FIG. 1 although clearly described above, the semiconductor substrate W is plasma-processed while the boundary 26 is moved to a lower region by relatively reducing the pressure in the chamber 12 as the first arranging means. Also, after the plasma process, the generation of plasma is stopped while the boundary 26 is far from the semiconductor substrate W to an upper region by relatively increasing the pressure in the chamber 12 as the second arranging means.

According to such a configuration, the plasma processing efficiency may be increased and charge-up damage by plasma may be reduced.

In this case, since a driver is not necessarily included in the plasma processing apparatus 11, the plasma processing apparatus 11 may be more easily manufactured at a low price. Also, since the holding stage 15 is not moved up and down, waste due to the up and down movement of the holding stage 15 is prevented from being generated, and thus a process may be performed while maintaining the inside of the chamber 12 clean. Also, the fixed holding stage 15 may be easily arranged in the first or second region by only adjusting the pressure in the chamber 12, i.e., without having to change a frequency of microwaves, or the like.

Also, generally, an electron temperature of plasma decreases when a pressure in the chamber 12 increases, and the electron temperature thereof increases when the pressure in the chamber 12 decreases This can be understood from a mean free path, but according to parallel-plate type plasma, an electron temperature of plasma decreases as a whole even when a pressure in the chamber 12 is high and an electron temperature of plasma in each location in the chamber 12 is the same. In other words, a distribution of electron temperatures of plasma is not generated in the chamber 12.

However, although it is clear from the above description, according to microwave plasma, a neighboring region immediately below the antenna unit 13 becomes a region with a high electron temperature (a so-called plasma generating region), and as a distance from the antenna unit 13 increases, plasma is diffused, and thus a region with a low electron temperature is formed. Accordingly, in the chamber 12, the electron temperature of plasma is high in the neighboring region immediately below the antenna unit 13, and the electron temperature of plasma is decreased as the distance from the antenna unit 13 increases. With respect to the plasma processing apparatus 11 according to the present invention, a distribution of electron temperatures of such plasma is formed. According to the present invention, the distribution of the electron temperatures of plasma is controlled by adjusting the pressure in the chamber 12, and thus the region where the fixed holding stage 15 is disposed may be the first region having a high electron temperature of plasma or the second region having a low electron temperature of plasma.

Here, in the plasma processing apparatus 11, the electron temperature of plasma in the chamber 12 is relatively higher during a CVD process than during an etching process, for example, increases up to 3 eV near the semiconductor substrate W. This is assumed to be an effect of gas used in a film-forming process. As such, the electron temperature of plasma is changed by the gas used in a film-forming process or the like, and the distribution of the electron temperatures of plasma is also changed. Thus, the control of the pressure in the chamber 12, a moving amount of the holding stage 15 in an up-and-down direction, or the like may be determined according to the etching process or the CVD process.

Also, according to the above embodiment, the electron temperature of plasma serving as the boundary of the first and second regions is 1.5 eV, but is not limited thereto, and may be any value.

In addition, in the above embodiment, plasma is generated after moving the semiconductor substrate W upward in the method for plasma-processing a semiconductor substrate, but the present invention is not limited thereto, and the semiconductor substrate W may be moved upward after generating plasma so as to arrange the semiconductor substrate W in the first region.

Also, in the above embodiment, the antenna unit 13 included in the plasma processing apparatus 11 includes the slot plate having the circular plate shape having the plurality of slot holes in the T-shape, but the present invention is not limited thereto, and a microwave plasma processing apparatus including an antenna unit having a skewer shape may be used. Also, a plasma processing apparatus generating diffused plasma, such as ICP, may be used.

Also, in the above embodiment, an example of using the MOS transistor as the semiconductor substrate is described, but the present invention is not limited thereto, and may be applied while manufacturing a CCD or the like.

While the present invention has been particularly shown and described with reference to exemplary embodiments thereof, it will be understood by those of ordinary skill in the art that various changes in form and details may be made therein without departing from the spirit and scope of the present invention as defined by the following claims.

A plasma processing apparatus and a method for plasma-processing a semiconductor substrate according to the present invention are effectively used when plasma processing efficiency needs to be increased while charge-up damage by plasma needs to be reduced.

In other words, according to the plasma processing apparatus and the method for plasma-processing a semiconductor substrate, the plasma processing efficiency can be increased by arranging a semiconductor substrate in a first region having a high electron temperature of plasma during a plasma process. Also, while stopping the generation of plasma, plasma damage caused while stopping the generation of plasma can be reduced by arranging the semiconductor substrate in a second region having a low electron temperature of plasma, thereby reducing charge-up damage by plasma.

What is claimed is:

1. A plasma processing method comprising:
holding a wafer on a holding stage disposed inside a processing chamber, the holding stage being configured to be movable;
generating plasma inside the processing chamber by a plasma generator to define a first processing region having an electron temperature higher than a predetermined value and a second processing region having an electron temperature lower than the predetermined value;
moving the holding stage toward the plasma generator for the wafer to be positioned in the first processing region;
performing the plasma processing of the wafer positioned in the first processing region;
moving the holding stage away from the plasma generator for the wafer to be positioned in the second processing region after completing the plasma processing of the wafer; and
stopping to generate plasma when the wafer is positioned in the second processing region after completion of the plasma processing.

2. The plasma processing method of claim 1, wherein the moving of the holding stage toward the plasma generator is performed before the generating of plasma.

3. The plasma processing method of claim 1, wherein the moving of the holding stage toward the plasma generator is performed after the generating of plasma.

4. The plasma processing method of claim 1, wherein the predetermined value is 1.5 eV.

5. The plasma processing method of claim 1, wherein the generating of plasma is performed by the plasma generator using microwave.

6. A plasma processing method comprising:
holding a wafer on a holding stage disposed in a processing chamber, the holding stage being configured to be movable;
generating plasma inside the processing chamber by a plasma source so as to form a first processing region having an electron temperature higher than a predetermined value and a second processing region having an electron temperature lower than the predetermined value;
moving the holding stage toward the plasma source for the wafer to be positioned in the first processing region; and
moving the holding stage away from the plasma source for the wafer to be to positioned in the second processing region after completing a plasma processing.

7. The plasma processing method of claim 6, further comprising.
stopping to generate plasma when the wafer is positioned in the second processing region after completion of the plasma processing.

8. The plasma processing method of claim 6, wherein the moving of the holding stage toward the plasma source is performed before the generating of plasma.

9. The plasma processing method of claim 6, wherein the moving of the holding stage toward the plasma source is performed after the generating of plasma.

10. The plasma processing method of claim 6, wherein the predetermined value is 1.5 eV.

11. A plasma processing method comprising:
holding a semiconductor substrate on a holding stage disposed inside a processing chamber, the processing chamber having a pressure;
generating plasma inside the processing chamber;
reducing the pressure to the extent that plasma near the semiconductor substrate has an electron temperature higher than a predetermined value;
plasma-processing the semiconductor substrate;
increasing the pressure to the extent that plasma near the semiconductor substrate has an electron temperature lower than the predetermined value; and
stopping to generate plasma.

12. The plasma processing method of claim 11, wherein the predetermined value is 1.5 eV.

13. The plasma processing method of claim 11, wherein the reducing of the pressure is performed before the plasma-processing of the semiconductor substrate.
